(19) United States
(12) Patent Application Publication
(10) Pub. No.: US 2025/0006755 A1
(43) Pub. Date: Jan. 2, 2025

(54) SEMICONDUCTOR DEVICE AND ELECTRONIC EQUIPMENT

(71) Applicant: SONY SEMICONDUCTOR SOLUTIONS CORPORATION, KANAGAWA (JP)

(72) Inventor: KOSUKE HAREYAMA, KANAGAWA (JP)

(21) Appl. No.: 18/695,367

(22) PCT Filed: Sep. 12, 2022
(86) PCT No.: PCT/JP2022/034020

§ 371 Date: Mar. 26, 2024

(30) Foreign Application Priority Data
Oct. 7, 2021 (JP) 2021-165815

(51) Int. Cl. H01L 27/146

(52) U.S. Cl. CPC H01L 27/14618; H01L 27/1462

(57) ABSTRACT

According to a semiconductor device, it is possible to obtain a favorable heat dissipation property, prevent falling of a material from a side surface of a substrate, and prevent generation of noise such as a flare caused by light reflected from members being present around a semiconductor element. The semiconductor device includes a substrate, a semiconductor element which is electrically connected to the substrate, a connecting member which electrically connects the substrate with the semiconductor element, a support portion which is provided on the substrate and supports a transparent member being located above the semiconductor element with respect to the substrate, a first resin portion provided on the semiconductor element, and a second resin portion which fills a space between the support portion and the first resin portion and covers the connecting member.

### TECHNICAL FIELD

The present disclosure relates to a semiconductor device and electronic equipment.

### BACKGROUND ART

In a semiconductor device provided with a packaged structure having an imaging element that is a semiconductor element mounted therein, from the viewpoint of holding a favorable operation state of the device to obtain a desired characteristic, it is important to dissipate heat generated from the imaging element serving as a heating element.

In addition, in the semiconductor device of this type, as a substrate to be electrically connected to the imaging element, for example, an organic substrate including an organic material such as a glass epoxy resin, and other materials are often used since they are relative inexpensive and are a material of the same type as that of a board on which the semiconductor device is to be mounted. The organic substrate is subjected to cutting processing, laser processing, punching processing, or other types of processing, for example, when being used for the packaged structure.

As described above, in the packaged structure, in a case in which a to-be-processed surface such as a substrate side surface in the organic substrate is exposed, falling of the materials of the organic substrate (for example, glass cloth, a filler, resin, or the like) from the to-be-processed surface is concerned. A falling material from the to-be-processed surface of the organic substrate is, for example, attached onto the imaging element and appears in a captured image, resulting in a possible cause of a defection mode.

In view of this, for example, PTL 1 discloses such a configuration that a solid-state imaging element is mounted in a recess formed in a package main body serving as an organic substrate including resin such as an epoxy resin and a filler such as an epoxy resin having a thermal conductivity higher than that of air is filled between a side surface of the solid-state imaging element and a wall surface of the recess of the package main body. With such a configuration, it is considered that, since the wall surface of the recess of the package main body is covered with the filler, even if the wall surface of the recess is the to-be-processed surface that is subjected to cutting processing or other types of processing, falling of a material from the to-be-processed surface is prevented.

### CITATION LIST

### Patent Literature

[PTL 1]
JP 2013-145823A

### SUMMARY

### Technical Problem

In such a configuration disclosed in PTL 1, the solid-state imaging element is electrically connected to the package main body through multiple bonding wires that are a metal wire including gold or the like. The bonding wire has one end connected to a terminal provided in a peripheral edge portion of the solid-state imaging element and has the other end connected to a terminal provided in the package main body. Hence, the multiple bonding wires that are present around the solid-state imaging element reflect incident light emitted toward the packaged structure, possibly causing noise such as a flare in a captured image.

The present technique has an object of providing a semiconductor device and electronic equipment capable of obtaining a favorable heat dissipation property, preventing a material from falling off from a side surface of a substrate, and preventing generation of noise such as a flare caused by light reflected from members around a semiconductor element.

### Solution to Problem

A semiconductor device according to the present technique includes a substrate, a semiconductor element which is electrically connected to the substrate, a connecting member which electrically connects the substrate with the semiconductor element, a support portion which is provided on the substrate and supports a transparent member being located above the semiconductor element with respect to the substrate, a first resin portion provided on the semiconductor element, and a second resin portion which fills a space between the support portion and the first resin portion and covers the connecting member.

According to another mode of the semiconductor device of the present technique, the semiconductor device further includes a support metal portion which is provided on a back surface side of the substrate and supports the semiconductor element with respect to the substrate.

According to another mode of the semiconductor device of the present technique, in the semiconductor device, the first resin portion is provided so as to cover a connecting portion of the connecting member for the semiconductor element.

According to another mode of the semiconductor device of the present technique, in the semiconductor device, the semiconductor element has a pixel region including a large number of pixels on a front surface thereof and a peripheral region which is a region outside the pixel region and has a step formed on a side lower than the pixel region, and the first resin portion is provided on the peripheral region.

According to another mode of the semiconductor device of the present technique, in the semiconductor device, the second resin portion has a lower layer portion which covers a side surface of the semiconductor element, and an upper layer portion formed on the lower layer portion and covering the connecting member, and the lower layer portion is formed by a material having a thermal conductivity higher than that of the upper layer portion.

Electronic equipment according to the present technique includes a semiconductor device including a substrate, a semiconductor element which is electrically connected to the substrate, a connecting member which electrically connects the substrate with the semiconductor element, a support portion which is provided on the substrate and supports a transparent member being located above the semiconductor element with respect to the substrate, a first resin portion provided on the semiconductor element, and a second resin portion which fills a space between the support portion and the first resin portion and covers the connecting member.

### BRIEF DESCRIPTION OF DRAWINGS

FIG. 1 is a cross-sectional view of a configuration of a solid-state imaging device according to a first embodiment of the present technique.

FIG. 2 is an explanatory view of a method of manufacturing the solid-state imaging device according to the first embodiment of the present technique.

FIG. 3 is an explanatory view of the method of manufacturing the solid-state imaging device according to the first embodiment of the present technique.

FIG. 4 is an explanatory view of the method of manufacturing the solid-state imaging device according to the first embodiment of the present technique.

FIG. 5 is an explanatory view of advantageous effects of the solid-state imaging device according to the first embodiment of the present technique.

FIG. 6 is a cross-sectional view illustrating a configuration of a first modification example of the solid-state imaging device according to the first embodiment of the present technique.

FIG. 7 is a cross-sectional view of a configuration of a second modification example of the solid-state imaging device according to the first embodiment of the present technique.

FIG. 8 is a cross-sectional view illustrating a configuration of a solid-state imaging device according to a second embodiment of the present technique.

FIG. 9 is an explanatory view of a method of manufacturing a solid-state imaging device according to the second embodiment of the present technique.

FIG. 10 is an explanatory view of the method of manufacturing a solid-state imaging device according to the second embodiment of the present technique.

FIG. 11 is a cross-sectional view of a configuration of a solid-state imaging device according to a third embodiment of the present technique.

FIG. 12 is a cross-sectional view of a configuration of a modification example of the solid-state imaging device according to the third embodiment of the present technique.

FIG. 13 is a block diagram illustrating a configuration example of electronic equipment provided with any one of the solid-state imaging devices according to the embodiments of the present technique.

### DESCRIPTION OF EMBODIMENTS

The present technique intends to achieve enhancement of a heat dissipation property, prevention of falling of a material from a side surface of a substrate, and prevention of an image defection such as a flare, with a configuration including a first resin portion provided in such a manner as to form a wall shape on a semiconductor element, and a second resin portion provided in such a manner as to fill a space between a support portion supporting a transparent member on a substrate and the first resin portion and as to cover a connecting member such as a bonding wire.

Hereinafter, modes for carrying out the present technique (hereinafter referred to as “embodiments”) will be described with reference to the accompanying drawings. In the embodiments to be described below, as a semiconductor device, a solid-state imaging device including a solid-state imaging element serving as an example of a semiconductor element is taken as an example and will be described. Note that description of the embodiments will be given in the following order.
1. Configuration Example of Solid-State Imaging Device According to First Embodiment
2. Method of Manufacturing Solid-State Imaging Device According to First Embodiment
3. Modification Examples of Solid-State Imaging Device According to First Embodiment
4. Configuration Example of Solid-State Imaging Device According to Second Embodiment
5. Method of Manufacturing Solid-State Imaging Device According to Second Embodiment
6. Configuration Example of Solid-State Imaging Device According to Third Embodiment
7. Configuration Example of Electronic Equipment

### 1. Configuration Example of Solid-State Imaging Device According to First Embodiment

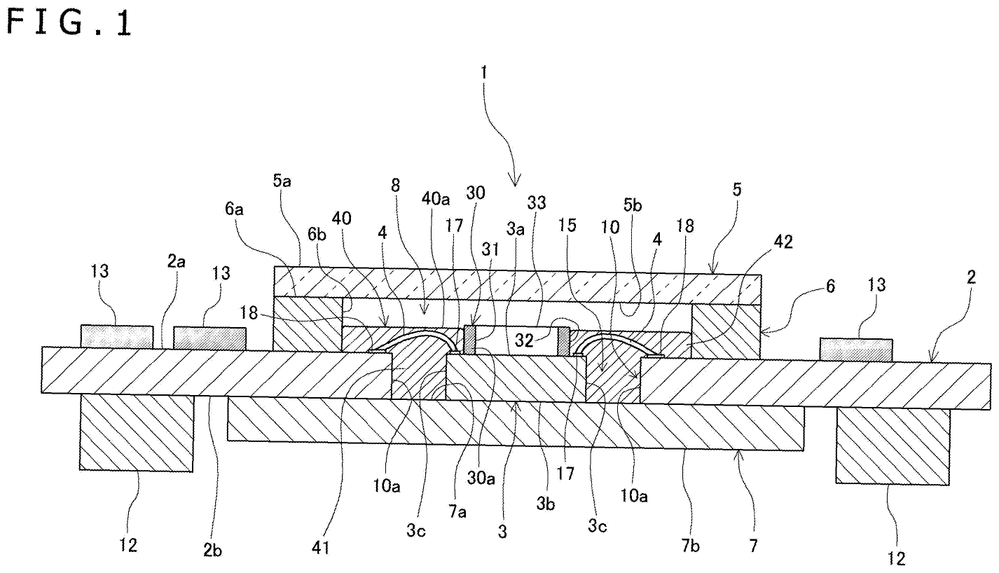

A configuration example of a solid-state imaging device 1 according to a first embodiment of the present technique will be described with reference to FIG. 1. Note that, in FIG. 1, a vertical direction is referred to as a vertical direction of the solid-state imaging device 1.

As illustrated in FIG. 1, the solid-state imaging device 1 includes a substrate 2, an image sensor 3 as a solid-state imaging element, multiple bonding wires 4 as a connecting member, glass 5 as a transparent member, a rib portion 6 as a support portion, and a metal plate 7 as a metal holding plate.

The solid-state imaging device 1 achieves an integrated packaged structure in which a cavity 8 as a closed space is formed on the image sensor 3 by surrounding the periphery of the image sensor 3 mounted on the metal plate 7 by the substrate 2 and closing the upper side of the image sensor 3 with the glass 5 provided on the substrate 2 through the rib portion 6. In particular, the solid-state imaging device 1 has a metal-back packaged structure in which the metal plate 7 having the image sensor 3 mounted thereon is provided on a back surface 2b side of the substrate 2.

The substrate 2 is, for example, an organic substrate including an organic material such as a glass epoxy resin which is a type of fiber-reinforced plastic, or other materials. The substrate 2 has an external shape in a rectangular plate and has a front surface 2a that is an upper surface as a plate face on one side and a back surface 2b that is a lower surface and a plate face opposite to the front surface 2a as a plate face on the other side. The front surface 2a and the back surface 2b are both horizontal surfaces. The substrate 2 has wiring layers, electrodes, predetermined circuits, and the like provided thereon.

A cross-sectional view illustrated in FIG. 1 is a cross-sectional view as viewed in a longitudinal direction of the external shape of the substrate 2 in a form of a rectangular plate. Specifically, a left-right direction in FIG. 1 serves as a lateral direction of the substrate 2, and a direction vertical to the paper surface on which FIG. 1 is drawn serves as a longitudinal direction of the substrate 2. It is assumed that the left-right direction in FIG. 1 be the left-right direction of the solid-state imaging device 1.

The substrate 2 has an opening 10 in the center portion thereof, the opening 10 providing a space for having the image sensor 3 disposed therein. The opening 10 is a hole portion penetrating the substrate 2 in a plate thickness direction (vertical direction) and has a rectangular opening shape corresponding to the external shape of the image sensor 3.

The opening 10 includes respective side surface portions 10a in four surrounding directions formed to be vertical to the plate face of the substrate 2. The opening 10 has opening dimensions larger than the outer dimensions of the image sensor 3 and is formed such that the whole image sensor 3 is accommodated in the opening 10 in plan view. The substrate 2 has a frame-like external shape owing to the presence of the opening 10.

It is to be noted that the configuration of the substrate 2 is not limited to that described above and may be other types of substrates. The substrate 2 may include a ceramic substrate or the like containing, as a material, ceramics such as alumina (Al₂O₃), aluminum nitride (AlN), or silicon nitride (Si₃N₄), for example.

The metal plate 7 is provided on the back surface 2b of the substrate 2 and is a metal support portion which supports the image sensor 3 with respect to the substrate 2. The metal plate 7 is a metal plate member having an external shape of a substantially rectangular plate form and is fixed to the substrate 2 in such a state as to be superimposed on the back surface 2b of the substrate 2 to close the opening 10 from below.

The metal plate 7 is fixed to the substrate 2 by, for example, being attached thereto with use of a die bonding material that is a resin adhesive having a relatively higher thermal conductivity or a TIM (Thermal Interface Material) to which a filler is added to increase its thermal conductivity, by being bonded thereto with use of brazing, or the like. As an adhesive which fixes the metal plate 7 to the substrate 2, for example, an epoxy resin adhesive, an acrylic resin adhesive, or the like is used. However, a method of fixing the metal plate 7 to the substrate 2 is not limited to any particular method and may use a method other than the method of fixing with use of an adhesive.

The metal plate 7 has a dimension shorter than that of the substrate 2 in the left-right direction. The metal plate 7 is provided in such a manner as to cover the middle portion of the back surface 2b of the substrate 2 in the left-right direction and to have both ends of the back surface 2b of the substrate 2 in the left-right direction exposed.

The metal plate 7 has an upper surface 7a and a lower surface 7b, both being horizontal surfaces. The metal plate 7 has a center portion of the upper surface 7a facing the cavity 8 side through the opening 10 of the substrate 2. Specifically, most part of the upper surface 7a of the metal plate 7 is covered with the substrate 2, and a portion of the upper surface 7a corresponding to the opening 10 becomes a non-covered portion which is not covered by the substrate 2. An exposed portion of the upper surface 7a of the metal plate 7 which is exposed by the opening 10 has the image sensor 3 mounted thereon.

As a metal material of the metal plate 7, from the viewpoint of the heat dissipation property, a material having a high thermal conductivity is preferable, while, from the viewpoint of preventing deformation caused by heat, a material having a low linear expansion coefficient is preferable. A metal material of the metal plate 7 includes, for example, copper (Cu), a copper alloy, tungsten (W), aluminum (Al), stainless steel (SUS), Fe—Ni—Co alloy, 42 alloy, and the like.

On the back surface 2b side of the substrate 2, multiple connectors 12 are provided as external connection terminals. The connector 12 is a plug which electrically connects the solid-state imaging device 1 to a circuit substrate or the like of an external device. The connectors 12 are provided at two locations on the exposed portions of the back surface 2b of the substrate 2 on sides of both ends of the metal plate 7 in the left-right direction.

The connector 12 has an external shape of a substantially quadrangular prism having a substantially rectangular transverse plane shape, and forms a projecting portion which projects from the back surface 2b in a shape extending along the longitudinal direction of the substrate 2. Two of the connectors 12 are disposed along edge portions of the substrate 2 on both ends of the left-right direction and in such a manner as to be parallel to each other. On the back surface 2b of the substrate 2, the metal plate 7 is provided between the left and right connectors 12.

The connector 12 has a configuration in which a wiring portion such as a metal lead portion is provided at a predetermined location of a resin main body constituting the external shape thereof. The connector 12 has a predetermined fitting shape corresponding to a fitted portion in which the connector 12 is fitted. The connector 12 is mounted on the back surface 2b of the substrate 2 by soldering or the like such that the wiring portion is electrically connected to a wiring portion formed in the substrate 2.

As described above, the solid-state imaging device 1 is configured as an image sensor-connector package having the connectors 12. It is to be noted that the external connection terminals of the solid-state imaging device 1 are not limited to the connectors 12 and may be PGA (Pin Grid Array) or the like in which multiple pins are disposed in a grid point manner.

In addition, on the front surface 2a side of the substrate 2, multiple front surface components 13 such as capacitors and resistors are mounted at predetermined locations.

The image sensor 3 is provided in such a state as to be fixed to the metal plate 7 and electrically connected to the substrate 2. The image sensor 3 is a semiconductor element including a semiconductor substrate including silicon (Si) that is one example of semiconductors. The image sensor 3 is a chip in a rectangular plate shape and has a front surface 3a that is an upper plate face as a light receiving surface and a back surface 3b that is a plate face opposite to the front surface 3a. In addition, the image sensor 3 has respective side surface portions 3c in four surrounding directions which are formed to be vertical to the plate faces thereof.

The image sensor 3 is mounted at the center portion of the upper surface 7a of the metal plate 7 by use of a die bonding material or the like, with the back surface 3b side thereof facing the metal plate 7 side. The image sensor 3 has substantially the same plate thickness as the substrate 2, for example, and is provided such that the front surface 3a is positioned to be substantially flush with the front surface 2a of the substrate 2.

The image sensor 3 is provided so as to be positioned at the center portion of the opening 10 of the substrate 2, in plan view. At the periphery of the image sensor 3, a space between the image sensor 3 and the substrate 2 is formed.

More specifically, the image sensor 3 has such a configuration that the respective side surface portions 3c in the four surrounding directions are opposed to the respective side surface portions 10a of the opening 10 in such a manner as to be spaced apart from each other and that a groove 15 is formed around the image sensor 3. The groove 15 forms a transverse plane shape taken along a rectangular shape, in a state in which the side surface portions 3c of the image sensor 3 are set to be inner side surfaces of the groove 15, the side surface portions 10a of the opening 10 are set to be outer side surfaces of the groove 15, and the upper surface 7a of the metal plate 7 is set to be a bottom surface of the groove 15, and is formed in a frame-like manner along the outer shape of the image sensor 3.

The image sensor 3 has multiple light-receiving elements (photoelectric conversion elements) formed on the front surface 3a thereof. The image sensor 3 according to the present embodiment is a CMOS (Complementary Metal Oxide Semiconductor) type image sensor. However, the image sensor 3 may be other imaging elements such as a CCD (Charge Coupled Device) type image sensor.

The image sensor 3 has a pixel region including a large number of pixels on the front surface 3a side, as a light receiving portion, the pixels being formed in a predetermined array such as a Bayer array, for example, with a region around the pixel region set as a peripheral region. The peripheral region has a predetermined peripheral circuit formed therein. The pixel region includes an effective pixel region in which generation, amplification, and reading out of signal charges are carried out by photoelectric conversion in each pixel. The pixels in the pixel region each have a photodiode as a photoelectric conversion section having a photoelectric conversion function and multiple pixel transistors.

A color filter and an on-chip lens are formed on the front surface 3a of the image sensor 3 in such a manner as to correspond to each pixel, with an antireflective film including an oxide film and the like, a planarizing film including an organic material, or the like being interposed between the semiconductor substrate and the color filter and the on-chip lens. Light entering the on-chip lens passes through the color filter, the planarizing film, and the like and is thereby received by the photodiode.

As a configuration of the image sensor 3, for example, there are configurations such as a front-illuminated (Front Side Illumination) image sensor in which a pixel region is formed on a front surface side of a semiconductor substrate, a back-illuminated (Back Side Illumination) image sensor in which a photodiode and the like are disposed in reverse to enhance transmittance of light and a back surface of a semiconductor substrate is set as a light receiving surface, and an image sensor having a one-chip structure obtained by stacking peripheral circuits of pixel groups. However, the image sensor 3 according to the present technique is not limited to these configurations described above.

The bonding wire 4 is a member which electrically connects the substrate 2 to the image sensor 3. The bonding wire 4 is provided in plural number around the image sensor 3. The bonding wire 4 is provided in such a manner as to straddle between the front surface 2a of the substrate 2 and the front surface 3a of the image sensor 3, in a curved form projecting upward like an arch or in a bending form, for example.

The bonding wire 4 is a thin metal wire including, for example, Au (gold) or Cu (copper). The bonding wire 4 has one end thereof connected to a pad electrode 17 formed in the peripheral region on the front surface 3a of the image sensor 3, while having the other end thereof connected to a lead electrode 18 formed on the front surface 2a of the substrate 2, thereby achieving electrical connection between these electrodes. These electrodes are respective terminals of the image sensor 3 and the substrate 2 for transmission and reception of signals to the outside and are formed as a metal film including, for example, a metal material such as Al (aluminum), Au (gold), Ag (silver), or Cu (copper).

The glass 5 is provided in such a manner as to cover the opening 10 of the substrate 2 from above. The glass 5 is an example of a transparent member which serves as an optical window, has an external shape in a form of a rectangular plate, and has a lower surface 5b which is a plate face on the side opposed to the image sensor 3, and an upper surface 5a which is opposite to the lower surface 5b.

The glass 5 is provided on a light receiving side of the image sensor 3, being in parallel to the image sensor 3 and spaced apart therefrom at a predetermined interval. The glass 5 is supported being fixed to the substrate 2 with the rib portion 6. The glass 5 has outer dimensions larger than the dimensions of the external shape of the opening 10 of the substrate 2 in plan view.

The glass 5 typically transmits various types of light rays emitted from an optical system such as a lens that is positioned above the glass 5. The light ray passing through the glass 5 enters the light receiving surface of the image sensor 3 through the cavity 8. The glass 5 has a function of protecting the light receiving surface of the image sensor 3. It is to be noted that, as the transparent member according to the present technique, in place of the glass 5, for example, a plastic plate, a silicon plate which transmits infrared light only, or the like can be used.

The rib portion 6 is provided on the substrate 2 and is a support portion which includes resin and supports the glass 5 positioned above the image sensor 3 with respect to the substrate 2. The rib portion 6 is provided outside a portion at which the lead electrode 18 is formed on the front surface 2a of the substrate 2, in such a manner as to surround an opening edge portion of the opening 10. Accordingly, the rib portion 6 is provided so as to surround the image sensor 3 along the external shape thereof, in plan view.

The rib portion 6 serves as a pedestal portion for the glass 5 with respect to the substrate 2. The rib portion 6 is interposed between the front surface 2a of the substrate 2 and the lower surface 5b of the glass 5, and forms the cavity 8 between the substrate 2 and the glass 5. The rib portion 6 has an upper surface 6a along the horizontal plane and fixes the glass 5 on the upper surface 6a, for example, via an adhesive such as a thermosetting resin. The rib portion 6 functions as a sealing portion which seals the periphery of the cavity 8 and prevents moisture (water vapor), dust, or the like from entering the cavity 8 from outside, along with the glass 5.

The rib portion 6 is formed in a wall shape all around the circumference thereof along the outer shape of the glass and is provided so as to form a rectangular frame in plan view. Accordingly, the rib portion 6 has four wall portions which form a rectangular shape in plan view. The rib portion 6 is provided at a position in a range of the external shape of the glass 5, along the outer edge of the glass 5, in plan view. The rib portion 6 is provided such that the outer side surface of the rib portion 6 is substantially flush with the outer side surface of the glass 5, for example.

A material of the rib portion 6 includes, for example, a photosensitive adhesive such as a UV (ultraviolet) curable resin that is an acrylic resin, a thermosetting resin such as an epoxy resin, or a mixed agent of these resins. The rib portion 6 is formed on the front surface 2a of the substrate 2 by molding the material with use of a molding die, applying the material with a dispenser, patterning the material through photolithography, or the like.

In a case in which the rib portion 6 includes a resin material, the rib portion 6 functions as an adhesive which adheres the substrate 2 and the glass 5 in a state in which they are spaced apart from each other. However, the rib portion 6 may be provided by attaching a structural body including ceramic such as glass, an inorganic material such as metal or silicon, or plastic, for example, to the substrate 2 and the glass 5 via an adhesive or the like.

In the solid-state imaging device 1 having the configuration described above, light being transmitted through the glass 5 passes through the cavity 8 and is received by the light-receiving element included in each pixel disposed in the pixel region of the image sensor 3 to thereby be detected.

The solid-state imaging device 1 having the configuration described above includes a bank-like resin portion 30 as a first resin portion and a covering resin portion 40 as a second resin portion on the image sensor 3 and at the periphery of the image sensor 3.

The bank-like resin portion 30 is a resin portion in a bank-like shape which is provided on the image sensor 3. The bank-like resin portion 30 is provided in the peripheral region in such a manner as to surround the pixel region on the front surface 3a of the image sensor 3.

The bank-like resin portion 30 is formed in a wall-like shape all around the circumference along the external shape of the image sensor 3 at a position in the range of the external shape of the image sensor 3, in such a manner as to form a rectangular frame shape in plan view. Hence, the bank-like resin portion 30 has four wall portions 30a which form a rectangular shape in plan view. The bank-like resin portion 30 has an inner wall surface 31 and an outer wall surface 32 vertical to the front surface 3a of the image sensor 3, in each of the wall portions 30a in the four surrounding directions. The bank-like resin portion 30 is provided on an inner side of a position at which the pad electrode 17 is formed.

A height of the bank-like resin portion 30 is not limited to any particular value, and the bank-like resin portion 30 is provided to be lower in height than an upper end surface of the rib portion 6. More specifically, the bank-like resin portion 30 is provided such that an upper end surface 33 thereof is positioned below the lower surface 5b of the glass 5.

The bank-like resin portion 30 is formed with use of a resin material having a thermal conductivity higher than that of air. A material of the bank-like resin portion 30 includes, for example, a photosensitive resin such as a UV (ultraviolet) curable resin that is an acrylic resin, a thermosetting resin such as an epoxy resin, or a mixed agent of these resins. The bank-like resin portion 30 is formed on the front surface 3a of the image sensor 3 by applying the material with a dispenser, patterning the material through photolithography, or the like. It is to be noted that the bank-like resin portion 30 has an insulating property.

The covering resin portion 40 is a resin portion which is provided to fill a space between the rib portion 6 and the bank-like resin portion 30 and cover the bonding wire 4. The covering resin portion 40 is a thermal conductive resin portion which is formed by a resin material having a thermal conductivity.

In the present embodiment, the covering resin portion 40 is provided to fill the groove 15 that is a gap between the substrate 2 and the image sensor 3 and cover the bonding wire 4 in whole. Accordingly, the covering resin portion 40 has a groove filling portion 41 which is a portion filled into the groove 15, and a wire covering portion 42 which is a portion above the groove filling portion 41 and covers the bonding wire 4, as a division defined by a formation site at which each portion is formed. The groove filling portion 41 and the wire covering portion 42 are portions continuous to each other and form an integrated covering resin portion 40.

The groove filling portion 41 is a lower portion of the covering resin portion 40 and is a portion which fills the groove 15 formed by the side surface portion 3c of the image sensor 3, the side surface portion 10a of the substrate 2, and the upper surface 7a of the metal plate 7. The wire covering portion 42 is an upper portion of the covering resin portion 40 and is a portion which covers the whole of the range surrounded by the rib portion 6 outside the bank-like resin portion 30. The wire covering portion 42 achieves the state in which the multiple bonding wires 4 provided between the portion outside the bank-like resin portion 30 on the front surface 3a of the image sensor 3 and the portion on the inner side of the rib portion 6 on the front surface 2a of the substrate 2 are filled with the covering resin portion 40.

As for the inner side of the wire covering portion 42, the bank-like resin portion 30 serves as a levee, thereby preventing the resin from entering the pixel region on the front surface 3a of the image sensor 3. The upper surface 40a of the covering resin portion 40 that is an upper surface of the wire covering portion 42 is a flat surface, and located, for example, at a position higher than the upper end of the bonding wire 4 forming an arch shape and a position lower than the upper end surface 33 of the bank-like resin portion 30. It is to be noted that the upper surface 40a of the covering resin portion 40 may be substantially flush with or may be flush with the upper end surface 33 of the bank-like resin portion 30.

The covering resin portion 40 is formed by filling a resin material at the periphery of the image sensor 3 and curing the resin material, in a state in which the image sensor 3 is supported through the metal plate 7 to the substrate 2 having the rib portion 6 formed thereon and the bank-like resin portion 30 is provided on the image sensor 3. The covering resin portion 40 is formed by application of the resin material by a dispenser, for example. However, the covering resin portion 40 may be formed, for example, by molding of the resin material with use of a molding die, or the like.

The covering resin portion 40 is formed by a resin material having a thermal conductivity higher than that of air. As the resin material forming the covering resin portion 40, for example, a thermosetting resin such as a phenolic resin, a silicone resin, an acrylic resin, an epoxy resin, an urethane resin, a silicon resin, or a polyether amide resin, a thermoplastic resin such as polyamide imide, polypropylene, or liquid crystal polymer, a photosensitive resin such as a UV curable resin that is an acrylic resin, rubber, or other known resin materials having a relatively high thermal conductivity are used alone or in combination.

In addition, when the resin material forming the covering resin portion 40 contains a thermal conductive filler having a high thermal conductivity, the thermal conductivity of the covering resin portion 40 can be enhanced. As the filler, for example, a known material such as a material including silicon oxide as a main component or alumina is used. It is to be noted that the covering resin portion 40 has an insulating property.

As for the resin material forming each of the bank-like resin portion 30 and the covering resin portion 40, as the resin material forming the covering resin portion 40, a material having a lower viscosity than that of the resin material forming the bank-like resin portion 30 is used. As the resin material forming the bank-like resin portion 30, in order to maintain the wall-like structure owing to the bank-like resin portion 30 on the front surface 3a of the image sensor 3, a material having a relatively high viscosity (for example, a paste-like material) is used. In contrast, as the material forming the covering resin portion 40, in order to fill the resin material in the groove 15 or the like which is a relatively narrow space, a material having a relatively low viscosity (for example, a liquid material) is used.

As described above, in a case in which the viscosity of the resin material forming the bank-like resin portion 30 is referred to as a first viscosity, as the resin material forming the covering resin portion 40, the resin material having a second viscosity that is lower than the first viscosity is used. However, the bank-like resin portion 30 and the covering resin portion 40 may be portions formed by the same resin material with each other.

As described above, in the solid-state imaging device 1, the bank-like resin portion 30 is provided in the peripheral region of the image sensor 3 by the resin material having a relatively high viscosity, and the covering resin portion 40 covering all of the upper surface 7a of the metal plate 7 in the groove 15, the side surface portion 3c of the image sensor 3, and the side surface portion 10a of the substrate 2 as well as the bonding wire 4 is provided outside the bank-like resin portion 30. In a configuration provided with the bank-like resin portion 30 and the covering resin portion 40, the cavity 8 is a space portion above the image sensor 3 and formed by the bank-like resin portion 30, the upper surface 40a of the covering resin portion 40, the lower surface 5b of the glass 5, and the inner side surface 6b of the rib portion 6.

### 2. Method of Manufacturing Solid-State Imaging Device According to First Embodiment

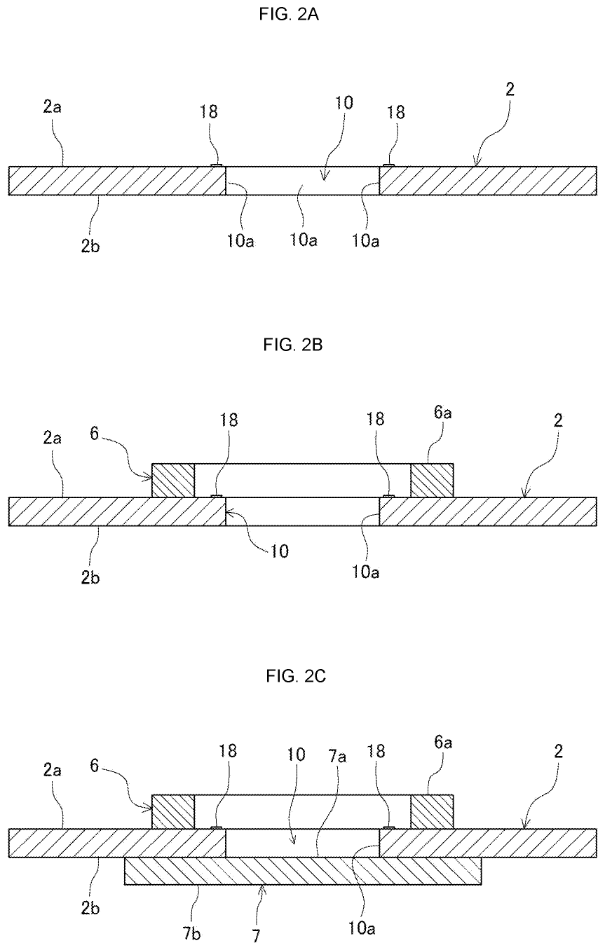

An example of a method of manufacturing the solid-state imaging device 1 according to the first embodiment will be described with reference to FIG. 2 to FIG. 4.

In the method of manufacturing the solid-state imaging device 1, first, as illustrated in FIG. 2A, the substrate 2 having the opening 10 is prepared. The substrate 2 is, for example, an organic substrate, and the opening 10 is formed by, for example, processing such as cutting processing, laser processing, or punching processing. In the substrate 2, the side surface portion 10a of the opening 10 becomes a to-be-processed surface. In the vicinity of the opening 10 in the front surface 2a, the lead electrode 18 which receives connection of the bonding wire 4 is formed.

Next, as illustrated in FIG. 2B, a process of forming the rib portion 6 on the substrate 2 is carried out. The rib portion 6 is formed into a rectangular shape by molding a material such as a thermosetting resin with use of a molding die. It is to be noted that the rib portion 6 may be formed by application of the material by a dispenser, patterning the material with use of photolithography, or the like. In addition, in a case in which the rib portion 6 is a portion including a structural body formed by a material such as metal or plastic, the structural body forming the rib portion 6 is attached to the front surface 2a of the substrate 2 via an adhesive or the like.

Next, as illustrated in FIG. 2C, a process of providing the metal plate 7 on the back surface 2b of the substrate 2 is carried out. The metal plate 7 is fixed to the substrate 2, for example, through adhering with use of a die bonding material having a relatively high thermal conductivity, a TIM material to which a filler for increasing the thermal conductivity is added, or the like. It is to be noted that the metal plate 7 may be fixed to the substrate 2 by bonding through brazing or the like. In addition, in place of the substrate 2, a substrate with a metal in which a metal plate is attached to the substrate such as an organic substrate in advance may be used. Owing to this, a process of attaching the metal plate 7 to the substrate 2 is omitted.

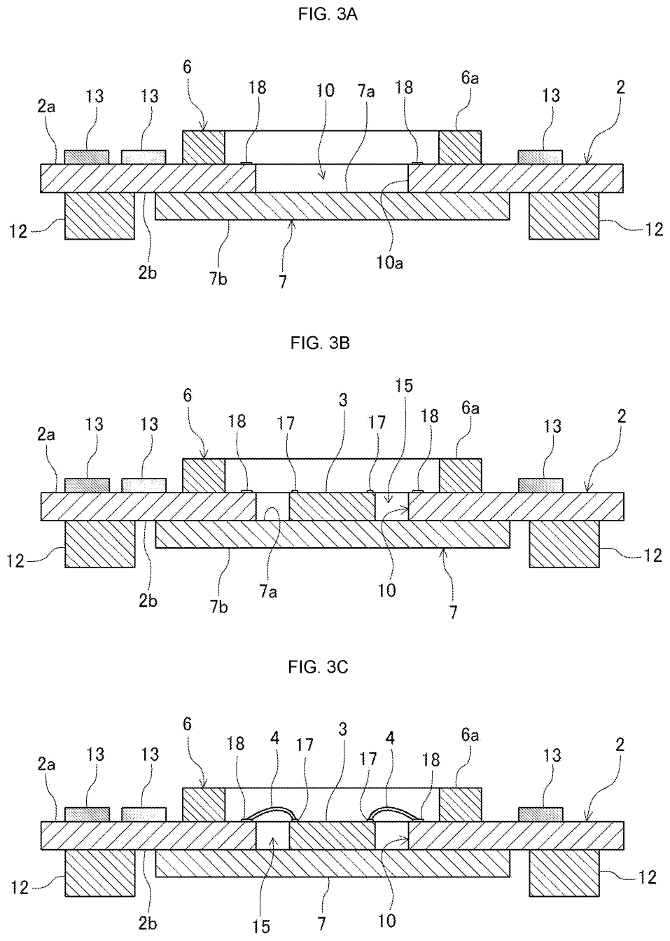

Subsequently, as illustrated in FIG. 3A, mounting of the connector 12 to the back surface 2b of the substrate 2 and mounting of the front surface component 13 to the front surface 2a of the substrate 2 are carried out. The connector 12 and the front surface component 13 are mounted to predetermined respective portions of the back surface 2b and the front surface 2a of the substrate 2 by soldering or the like to thereby be electrically connected to the substrate 2.

Next, as illustrated in FIG. 3B, a die bonding process of mounting the image sensor 3 to the metal plate 7 is carried out. The image sensor 3 is obtained as a sensor chip by dicing a silicon wafer formed in a state in which sensor portions are two-dimensionally continuous to each other into individual pieces. The image sensor 3 is set at a predetermined position with respect to an exposed portion of the upper surface 7a of the metal plate 7 in the opening 10 with a chip mounter or the like and is subjected to die bonding with a die bonding material.

Then, as illustrated in FIG. 3C, a wire bonding process of providing the bonding wire 4 which electrically connects the image sensor 3 and the substrate 2 is carried out. In this process, the multiple pad electrodes 17 provided on the front surface 3a of the image sensor 3 and the multiple lead electrodes 18 provided on the front surface 2a of the substrate 2 are connected to each other by the bonding wires 4 to be electrically connected to each other. The bonding wire 4 is wired so as to form a predetermined shape projecting upward like an arch or the like, for example.

As described above, the image sensor 3 is fixed to the substrate 2 through the metal plate 7, achieving a state in which the image sensor 3 is electrically connected to the substrate 2.

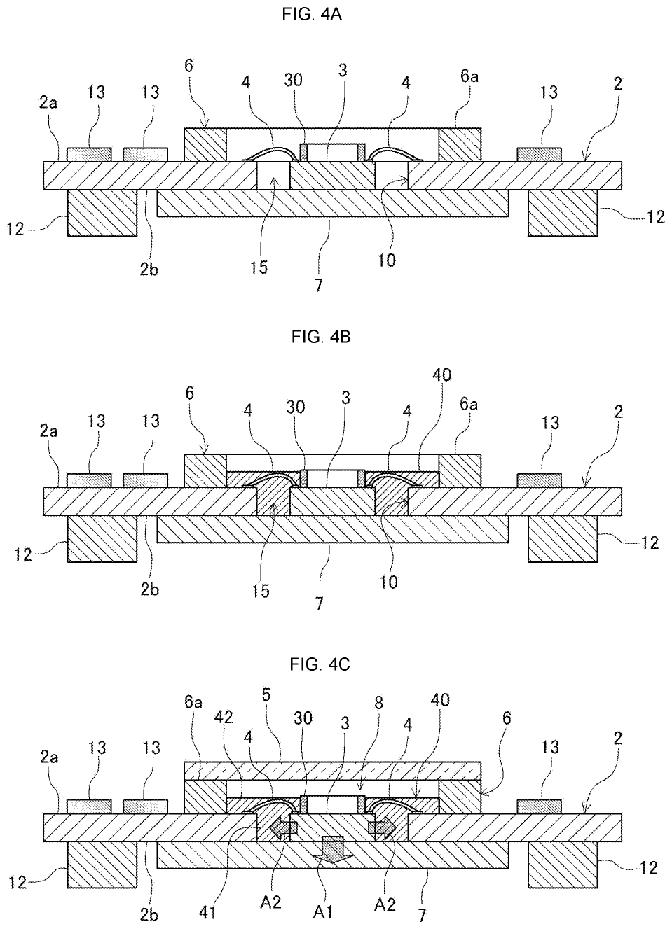

Subsequently, as illustrated in FIG. 4A, a process of forming the bank-like resin portion 30 is carried out. In this process, first, the resin material that becomes the bank-like resin portion 30 is applied to a predetermined portion of the peripheral region on the front surface 3a of the image sensor 3, with a dispenser. Here, the resin material that becomes the bank-like resin portion 30 is applied so as to form a rectangular frame in plan view, while being discharged from a nozzle of the dispenser.

The resin material applied to the front surface 3a of the image sensor 3 is solidified at a predetermined timing and becomes the bank-like resin portion 30. In a case in which the resin material that becomes the bank-like resin portion 30 is a thermosetting resin, after the process of applying the resin material, a process of heating the applied resin material at a predetermined temperature and curing the applied resin material is carried out. In addition, in a case in which the resin material that becomes the bank-like resin portion 30 is the UV curable resin, the process of curing the applied resin material is carried out by application of a UV ray to the applied resin material. It is to be noted that the bank-like resin portion 30 may be formed by, for example, patterning the resin material with use of a photolithography technique, or the like.

Next, as illustrated in FIG. 4B, a process of forming the covering resin portion 40 is carried out. In this process, first, a space portion at the periphery of the image sensor 3, specifically, in a space portion outside the bank-like resin portion 30 and inside the rib portion 6, the resin material in a liquid state that becomes the covering resin portion 40 is applied by a dispenser or the like. Here, the resin material that becomes the covering resin portion 40 is applied in such a manner as to fill the groove 15 in whole to a level of a height at which the bonding wire 4 is entirely covered.

The resin material applied to the periphery of the image sensor 3 is solidified at a predetermined timing and becomes the covering resin portion 40. In a case in which the resin material that becomes the covering resin portion 40 is a thermosetting resin, after the process of applying the resin material, a process of heating the applied resin material at a predetermined temperature and curing the applied resin material is carried out. In addition, in a case in which the resin material that becomes the covering resin portion 40 is a UV curable resin, a process of applying a UV ray to the applied resin material to cure the resin material is carried out.

Also, as illustrated in FIG. 4C, a process of mounting the glass 5 is carried out. Here, a glass sealing process of attaching the glass 5 onto the rib portion 6 is carried out. The glass 5 is obtained by cutting, for example, a glass plate having a predetermined shape through dicing into rectangular pieces.

The glass 5 is adhered and fixed to the upper surface 6a of the rib portion 6 so as to close the opening on an upper side of the upper surface 6a, via an adhesive or the like. For example, in a case in which an adhesive has a thermosetting property, in a state in which the glass 5 is mounted on the rib portion 6 via an adhesive, a heating (curing) process for curing the adhesive is carried out. As a result of attaching the glass 5, a cavity 8 is formed above the image sensor 3. According to the manufacturing process described above, the solid-state imaging device 1 is obtained.

According to the solid-state imaging device 1 of the present embodiment described above, a favorable heat dissipation property can be obtained, a material falling off from the side surface portion 10a of the substrate 2 can be prevented, and generation of noise such as a flare caused by light reflected from members around the image sensor 3 can be prevented. Such advantageous effects described above thus obtained will be described in more detail.

First, regarding the heat dissipation property, in the solid-state imaging device 1, the bank-like resin portion 30 is provided on the image sensor 3 mounted on the metal plate 7 provided on the back surface 2b of the substrate 2, and the covering resin portion 40 which fills the space surrounding the image sensor 3 and is formed in contact with the metal plate 7 is provided. With such a configuration described above, a heat dissipation path other than a heat dissipation path passing through the metal plate 7 can be secured, so that a higher heat dissipation property can be obtained. More specific details are as follows.

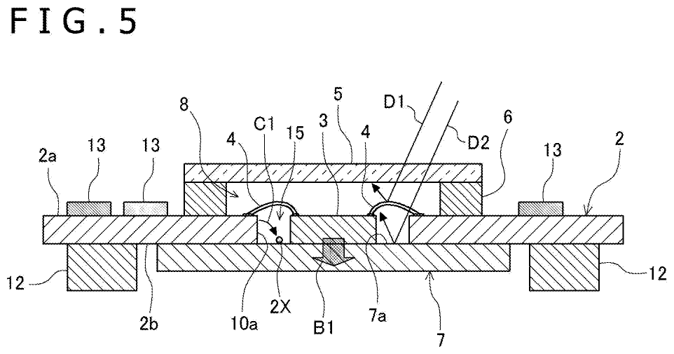

For example, as illustrated in FIG. 5, in the configuration not provided with the bank-like resin portion 30 and the covering resin portion 40, a heat dissipation path for heat generated in the image sensor 3 serving as a heating element is only a heat dissipation path which passes from the image sensor 3 to the lower side (the back surface 3b side) through the metal plate 7 (see an arrow B1). It is to be noted that FIG. 5 is a view of a configuration of a comparative example of the solid-state imaging device 1 according to the present embodiment.

In contrast, according to the solid-state imaging device 1 of the present embodiment, as illustrated in FIG. 4C, as for the heat generated in the image sensor 3, the metal plate 7 secures the heat dissipation path from the image sensor 3 to the lower side (the back surface 3b side) thereof (see an arrow A1), and the covering resin portion 40 secures the heat dissipation paths from the image sensor 3 to lateral sides (the side surface portions 3c side) thereof (see arrows A2). As for a heat dissipation effect produced by the covering resin portion 40, of the covering resin portion 40, the groove filling portion 41 provided in the groove 15 mainly acts. Hence, according to the solid-state imaging device 1, the heat dissipation path can be provided on the back surface 3b side and the side surface portions 3c side in the four surrounding directions of the image sensor 3, and heat can be released at each surface portion, so that a favorable heat dissipation property can be obtained.

Next, regarding falling of the material from the side surfaces of the substrate, for example, in the configuration of the comparative example illustrated in FIG. 5, since the side surface portion 10a that is a to-be-processed surface of the substrate 2 is exposed in the cavity 8, falling of the material of the organic substrate from the side surface portion 10a is concerned (see an arrow C1). A falling material 2X from the side surface portion 10a is, for example, a glass cloth, a filler, resin, or the like. The falling material 2X is generated as a result of application of shaking or impact at a time of using electronic equipment such as a camera apparatus mounted with the solid-state imaging device 1, for example, and is attached to the pixel region of the image sensor 3 to thereby appear in a captured image, possibly causing a defect mode.

In contrast, according to the solid-state imaging device 1 of the present embodiment, since the side surface portion 10a of the substrate 2 is entirely covered by the covering resin portion 40, a concern that the material of the organic substrate falls off from the side surface portion 10a is eliminated. Hence, defects in the captured image caused by the image sensor 3 can be prevented.

In addition, as for noise of the captured image, for example, in the configuration of the comparative example illustrated in FIG. 5, since the bonding wire 4 including gold or the like is exposed, light entering the cavity 8 is reflected on the bonding wire 4, possibly causing generation of noise such as a flare in the captured image (see an arrow D1). The light reflected on the bonding wire 4 is reflected by the glass 5 and the like and enters the pixel region of the image sensor 3, thereby causing generation of a flare or the like. Similarly, the light entering the cavity 8 is reflected on the exposed portion of the upper surface 7a of the metal plate 7 in the cavity 8, thereby causing noise to be generated in the captured image (see an arrow D2). In addition, the terminal such as the pad electrode 17 which receives connection of the bonding wire 4 may also cause generation of a flare as a result of the reflection of the light entering the cavity 8.

In contrast, according to the solid-state imaging device 1 of the present embodiment, the covering resin portion 40 covers the bonding wire 4 and the exposed portion of the upper surface 7a of the metal plate 7, making it possible to shield these portions from the light, so that reflected light attributable to the light entering the cavity 8 which causes noise such as a flare can be prevented. Hence, it is possible to secure the quality of the captured image.

It is favorable that the material of the covering resin portion 40 be a resin material which has a low reflectivity and such a physical property as to absorb light, from such a viewpoint that light passing through the glass 5 is reflected on the front surface (upper surface 40a) of the covering resin portion 40 and then enters the light receiving portion of the image sensor 3 to prevent generation of a flare. As the material of the covering resin portion 40, for example, a resin material containing a black pigment such as carbon black or titanium black is used to allow the covering resin portion 40 to be a black portion, making it possible to cause the covering resin portion 40 to function as a light shielding section. In addition, subjecting the front surface of the covering resin portion 40 to emboss processing such as pearskin finish is also effective in terms of preventing generation of a flare. In terms of preventing generation of a flare, a material of the bank-like resin portion 30, as with the covering resin portion 40, a resin material which has a low reflectivity and such a physical property as to absorb light is favorable.

It is to be noted that, in order to prevent a flare caused by reflected light from the bonding wire 4 and the upper surface 7a of the metal plate 7, a method of forming a light-shielding film on the upper surface 5a or the lower surface 5b of the glass 5 by printing, deposition, or the like is available. However, according to such a method described, additional processes such as a printing process or a deposition process for forming the light-shielding film is required, causing higher processing costs and resulting in increased costs. In addition, when a light-shielding film is formed on the glass 5, angle limitation of incident light needs to be taken into account, and accordingly, it is not easy to take a countermeasure for this. In addition, in order to prevent reflection of light on the upper surface 7a of the metal plate 7 which causes generation of a flare, for example, there is a method of applying such special processing and treatment as metal processing as exemplified by matt treatment or blackening treatment such as black plating or painting. However, an increase in number of processes and an increase in costs are concerned in this method as well.

In this regard, according to the solid-state imaging device 1 of the present embodiment, there is no need to form the light-shielding film on the glass 5 or to subject the front surface of the metal plate 7 to metal treatment or the like, so that a flare can be prevented with low costs and with ease. Specifically, regarding the manufacturing method, only two processes, the process of forming the bank-like resin portion 30 and the process of forming the covering resin portion 40, may be added, so that manufacturing with low costs can be achieved. In particular, the glass as the light-shielding film is very expensive, so that it is possible to reduce the manufacturing costs effectively without using the glass as the light-shielding film. In addition, since the solid-state imaging device 1 has the bonding wire 4 and the exposed portion of the upper surface 7a of the metal plate 7 entirely covered with the covering resin portion 40, there is no need to take into account the angle limitation of incident light, so that a flare can be prevented easily.

### 3. Modification Examples of Solid-State Imaging Device According to First Embodiment

Modification examples according to the solid-state imaging device 1 of the first embodiment will be described below.

### First Modification Example

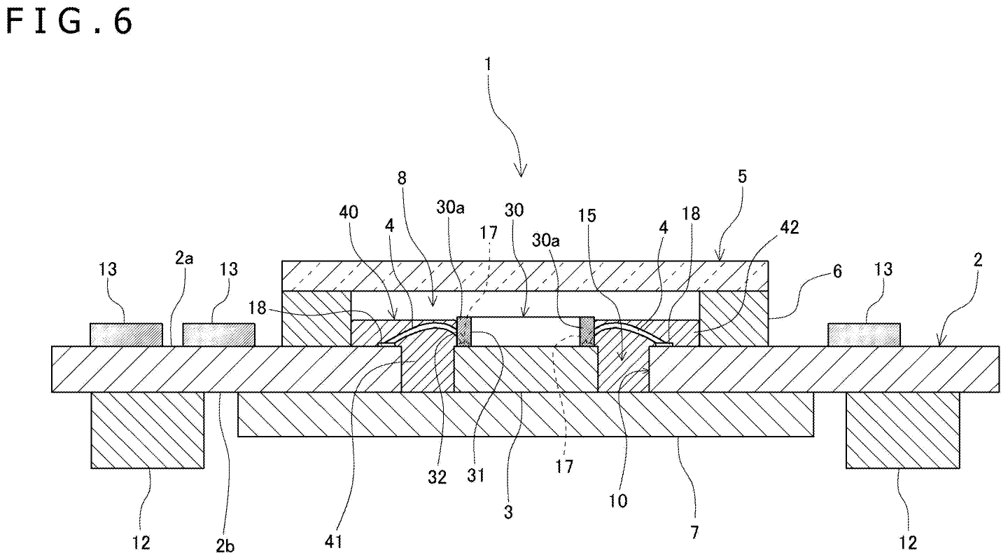

A first modification example relates to a layout of the bank-like resin portion 30 on the image sensor 3. As illustrated in FIG. 6, in the first modification example, the bank-like resin portion 30 is provided so as to cover the connecting portion of the bonding wire 4 for the image sensor 3.

The bank-like resin portion 30 is provided so as to entirely cover the pad electrode 17 to which the one end of the bonding wire 4 is connected. In other words, the configuration of this modification example adopts a structure in which the one end of the bonding wire 4 connected to the pad electrode 17 is accommodated in a lower portion of the bank-like resin portion 30.

For example, as illustrated in FIG. 6, the bank-like resin portion 30 is provided such that the inner wall surface 31 of each wall portion 30a is positioned on an inner side relative to the pad electrode 17 that becomes the connecting portion of the bonding wire 4 and that the outer wall surface 32 of each wall portion 30a is positioned on an outer side relative to the pad electrode 17. In this manner, the bank-like resin portion 30 is provided at a portion at which the pad electrode 17 formed in the peripheral region is formed on the front surface 3a of the image sensor 3 and covers the connecting portion of the bonding wire 4 for the image sensor 3.

The configuration of the first modification example is obtained, in the process of forming the bank-like resin portion 30, by having the connecting portion of the bonding wire 4 for the pad electrode 17 included in an application region of the resin material which becomes the bank-like resin portion 30. It is to be noted that, in the configuration of the first modification example, the bank-like resin portion 30 is only required to be provided so as to cover at least part of the connecting portion of the bonding wire 4 for the image sensor 3.

According to the configuration of the first modification example, on the front surface 3a of the image sensor 3, in addition to a region of the connecting portion on the one end side of the bonding wire 4, that is, a formation region of the pad electrode 17, a layout region of the bank-like resin portion 30 is not required to be secured separately. Accordingly, it is possible to reduce the peripheral region of the front surface 3a in the image sensor 3. Hence, a yield of the image sensor 3 can be enhanced, thereby achieving reduction in costs.

### Second Modification Example

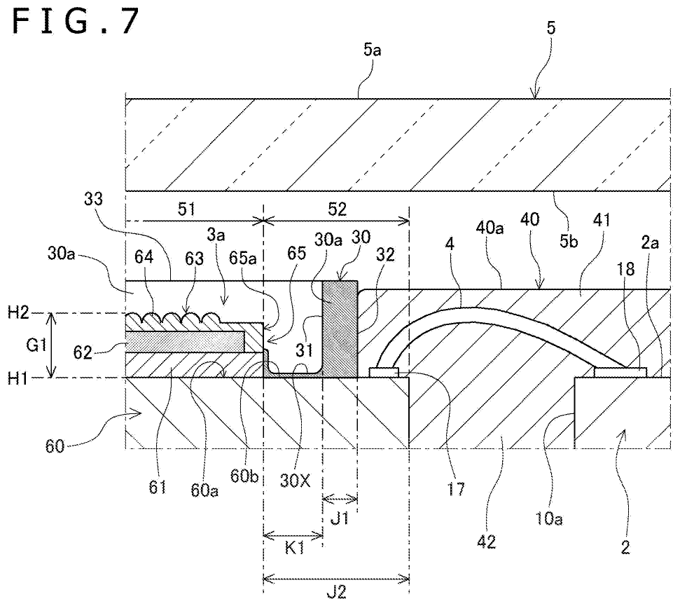

The second modification example relates to a configuration of the image sensor 3 and a layout of the bank-like resin portion 30 on the image sensor 3. As illustrated in FIG. 7, in the second modification example, the image sensor 3 has, on the front surface 3a, a pixel region 51 including a large number of pixels, and a peripheral region 52 which is outside the pixel region 51 and which forms a step on a lower side relative to the pixel region 51. With respect to the image sensor 3 having such a configuration described above, the bank-like resin portion 30 is provided on the peripheral region 52.

One example of the configuration of the image sensor 3 will be described. As illustrated in FIG. 7, the image sensor 3 has a semiconductor substrate 60 including a semiconductor such as silicon. The pixel region 51 is a captured region provided in the semiconductor substrate 60, and for example, has a large number of pixels provided in a predetermined array such as a Bayer array. The pixel region 51 includes an effective pixel region in which generation, amplification, and reading out of signal charges due to photoelectric conversion in each pixel are carried out. Each pixel includes a photodiode serving as a photoelectric conversion section having a photoelectric conversion function, and multiple transistors which carry out amplification, transfer, and the like of signal charges generated by the photodiode. The photodiode is formed in the semiconductor substrate 60.

A planarization film 61 having a light transmitting property is provided on an upper surface 60a that is one plate face of the semiconductor substrate 60, via an insulating film such as a silicon oxide film functioning as an antireflective film. The planarization film 61 is formed by, for example, an organic material such as resin having an insulating property. A color filter layer 62 is provided on the planarization film 61 and is demarcated into multiple color filters provided so as to correspond to respective pixels.

A lens layer 63 is formed on the color filter layer 62 and has multiple microlenses 64 formed so as to correspond to the photodiodes of the respective pixels. The lens layer 63 is formed so as to cover the entire front surface of the image sensor 3 with an organic material such as resin, for example. Light entering the microlenses 64 passes through the color filter layer 62, the planarization film 61, and the like to be received by the photodiode.

In this manner, in the pixel region 51, a layered structure 65 including the planarization film 61, the color filter layer 62, and the lens layer 63 is provided on the upper surface 60a that is the one plate face of the semiconductor substrate 60. It is to be noted that, although illustration is omitted, on the lower surface side of the semiconductor substrate 60, for example, a wiring layer having multiple wires stacked on top of another with an interlayer insulating film formed by a silicon oxide film or the like interposed therebetween is provided.

On the front surface 3a side of the image sensor 3 having such a configuration described above, a formation region of the layered structure 65 formed on the upper surface 60a of the semiconductor substrate 60 is set to the pixel region 51 only, and the peripheral region 52 is put into a state in which the upper surface 60a of the semiconductor substrate 60 is exposed, resulting in formation of a step G1 between the pixel region 51 and the peripheral region 52. Specifically, the layered structure 65 is selectively formed with respect to the pixel region 51, and with respect to the peripheral region 52 in which the upper surface 60a of the semiconductor substrate 60 is exposed, a film thickness of the pixel region 51 becomes greater upward by a film thickness of the layered structure 65, so that the step G1 is formed. Accordingly, a dimension of the step G1 is a dimension between a height position H1 of the upper surface 60a of the semiconductor substrate 60 and a height position H2 of an upper end of the lens layer 63 in a thickness direction (vertical direction) of the image sensor 3.

In this manner, in the image sensor 3, the peripheral region 52 having a smaller thickness is provided in such a manner as to form the step on the front surface 3a side in the pixel region 51. The peripheral region 52 is provided in whole at an outer edge portion of the image sensor 3 along the rectangular external shape of the image sensor 3. Also, the bank-like resin portion 30 is formed on the peripheral region 52 in which the upper surface 60a of the semiconductor substrate 60 is exposed at a position that is lower by the dimension of the step G1 than the pixel region 51. The bank-like resin portion 30 has a rectangular shape in plan view, along the formation region of the peripheral region 52, in such a manner as to surround the pixel region 51.

As illustrated in FIG. 7, the bank-like resin portion 30 is formed such that a wall thickness J1 of each of the wall portions 30a becomes smaller than a width dimension J2 of each side portion of the peripheral region 52 formed along a rectangular shape in plan view. In the example illustrated in FIG. 7, the bank-like resin portion 30 is formed to have each of the wall portions 30a positioned in the middle portion in the width direction (a left-right direction in FIG. 7, regarding the corresponding portion of the peripheral region 52 illustrated in FIG. 7) of each of the side portions of the peripheral region 52.

Thus, the bank-like resin portion 30 is provided with respect to the image sensor 3 such that a gap K1 is present between the inner wall surface 31 of each of the wall portions 30a and a side surface 65a of the layered structure 65 which forms the step G1. In this configuration, an exposed portion 60b of the upper surface 60a of the semiconductor substrate 60 is present between the bank-like resin portion 30 and the layered structure 65.

According to the configuration of the second modification example, since the pixel region 51 is higher than the peripheral region 52 provided with the bank-like resin portion 30 in a step-wise manner, it is possible to suppress or prevent the resin material or a component of the resin forming the bank-like resin portion 30 from entering the front surface of the lens layer 63 on the pixel region 51 side, or the like, due to a capillary phenomenon or the like. Specifically, as illustrated in FIG. 7, as for the resin material or the component of the resin forming the bank-like resin portion 30, also in a case in which a bleeding portion 30X called bleeding or the like is generated, the step due to the layered structure 65 with respect to the upper surface 60a is present, so that it is possible to suppress or prevent the bleeding portion 30X from reaching the front surface side of the pixel region 51, that is, the front surface side of the layered structure 65.

The example of FIG. 7 illustrates a state in which the bleeding portion 30X of the resin material forming the bank-like resin portion 30 extends through the exposed portion 60b of the upper surface 60a of the semiconductor substrate 60 and rides over the middle of the side surface 65a of the layered structure 65. Thus, by providing the step in the pixel region 51 in such a manner as to be higher than the peripheral region 52 provided with the bank-like resin portion 30, it is possible to prevent the bleeding portion 30X of the bank-like resin portion 30 from entering the pixel region 51.

It is to be noted that, in the configuration example described above, as for the step (inter-region step) between the pixel region 51 and the peripheral region 52, formation of the layered structure 65 in the pixel region 51 only contributes to a state in which the layer thickness of the layered structure 65 corresponds to a magnitude of the step, and the inter-region step may include a difference in layer thickness attributable to reduction (thinning) of the thickness of the semiconductor substrate 60 from the upper surface 60a side. Specifically, such a configuration that the inter-region step is secured by making the thickness of the semiconductor substrate 60 in the peripheral region 52 smaller than that of the semiconductor substrate 60 in the pixel region 51, in addition to selective formation of the layered structure 65 with respect to the pixel region 51, may be adoptable.

### 4. Configuration Example of Solid-State Imaging Device According to Second Embodiment

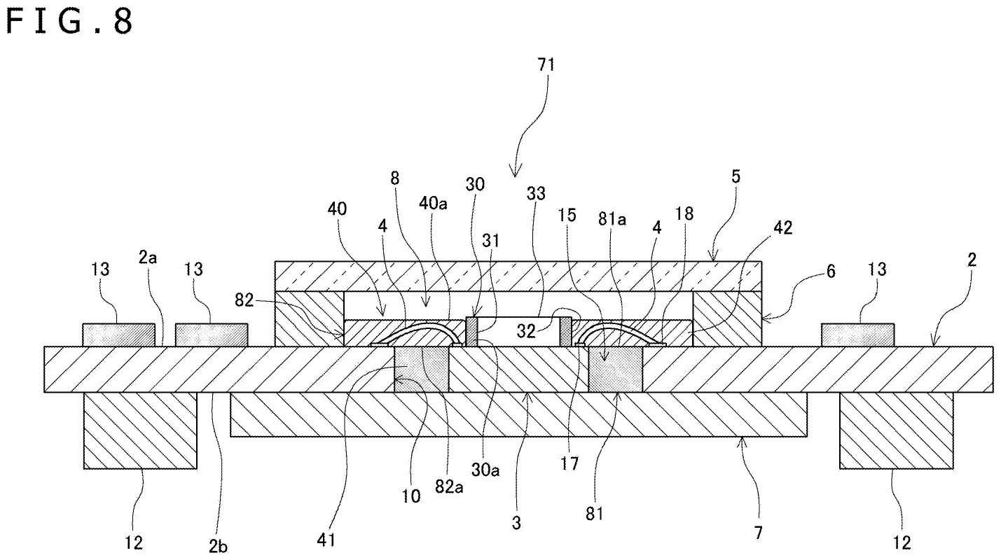

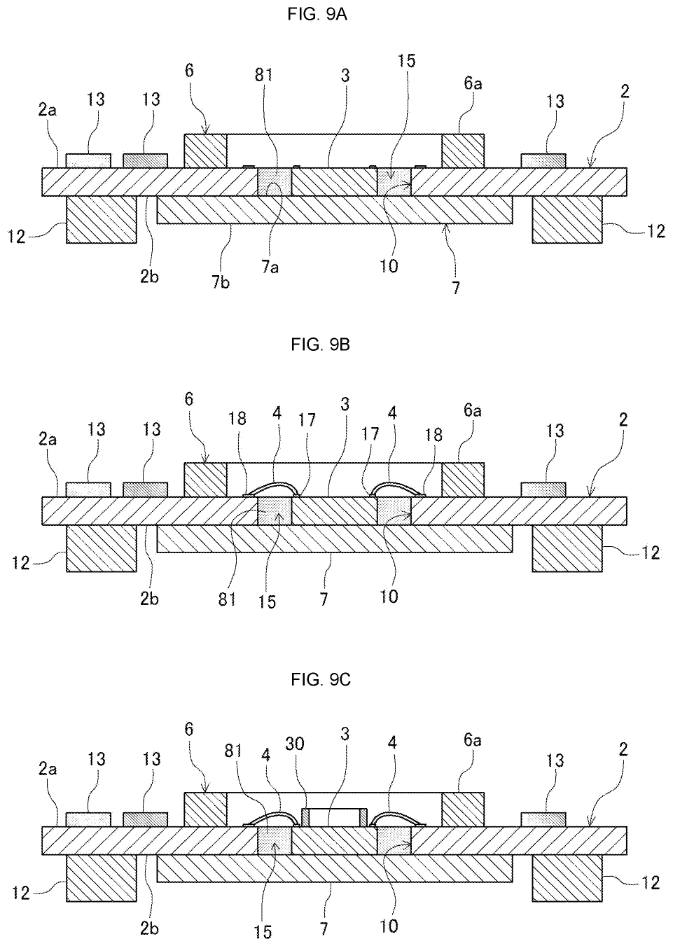

A configuration example of a solid-state imaging device 71 according to a second embodiment of the present technique will be described with reference to FIG. 8. In the embodiments described below, components common to those in the first embodiment are denoted by the same reference signs, and detailed description thereof is omitted as needed.

The solid-state imaging device 71 according to the present embodiment is different in configuration of the covering resin portion 40 from that in the first embodiment. As illustrated in FIG. 8, in the solid-state imaging device 71, the covering resin portion 40 has a lower layer portion 81 which covers the side surface portions 3c forming the side surfaces of the image sensor 3, and an upper layer portion 82 which is formed on the lower layer portion 81 and covers the bonding wire 4.

More specifically, in contrast to the first embodiment, the covering resin portion 40 according to the present embodiment has such a separated structure that the covering resin portion 40 is separated into upper and lower layers including the lower layer portion 81 and the upper layer portion 82. The lower layer portion 81 and the upper layer portion 82 are continuous to each other and form the covering resin portion 40 in an integrated manner.

The lower layer portion 81 is a portion which is the lower portion of the covering resin portion 40 and filled in the groove 15, mainly corresponding to the groove filling portion 41. The lower layer portion 81 fills the groove 15 and has a horizontal upper surface 81a flush with the front surface 2a of the substrate 2 or the front surface 3a of the image sensor 3 or both of them.

The upper layer portion 82 is the upper portion of the covering resin portion 40 and a portion of the covering resin portion 40 above the lower layer portion 81, mainly corresponding to the wire covering portion 42. The upper layer portion 82 is a portion covering the entire range surrounded by the rib portion 6 outside the bank-like resin portion 30. The upper layer portion 82 achieves a state in which the multiple bonding wires 4 are buried with the covering resin portion 40.

On an inner side of the upper layer portion 82, the bank-like resin portion 30 serves as a levee, preventing the resin from entering the pixel region at the front surface 3a of the image sensor 3. The upper surface of the upper layer portion 82 serves as the upper surface 40a of the covering resin portion 40. The upper layer portion 82 has a lower surface 82a that is a matching surface with respect to the upper surface 81a of the lower layer portion 81. The upper surface 81a of the lower layer portion 81 and the lower surface 82a of the upper layer portion 82 form a boundary surface of the lower layer portion 81 and the upper layer portion 82.

The lower layer portion 81 and the upper layer portion 82 are formed by resin materials different from each other. Also, the lower layer portion 81 is formed by a material having a thermal conductivity higher than that of the upper layer portion 82.

In a case in which a resin material having a second thermal conductivity is selected from the resin material forming the covering resin portion 40 described above as the resin material of the upper layer portion 82, as the resin material of the lower layer portion 81, a resin material having a first thermal conductivity higher than the second thermal conductivity is selected. When a resin material forming the lower layer portion 81 includes, for example, a thermal conductive filler having a high thermal conductivity, the thermal conductivity of the covering resin portion 40 can be enhanced.

It is to be noted that the boundary surface of the lower layer portion 81 and the upper layer portion 82 may be provided in the groove 15 in the vertical direction and may be provided above the groove 15. In a case in which the boundary surface is provided in the groove 15, the groove filling portion 41 is formed by the lower layer portion 81 and the lower portion of the upper layer portion 82, and the wire covering portion 42 is formed by the upper layer portion 82. In contrast, in a case in which the boundary surface is present above the groove 15, the groove filling portion 41 is formed by the lower layer portion 81, and the wire covering portion 42 is formed by the upper portion of the lower layer portion 81 and the upper layer portion 82. Specifically, the covering resin portion 40 may be provided such that the lower portion of the upper layer portion 82 is positioned in the groove 15 and part of the bonding wire 4 is covered with the upper portion of the lower layer portion 81.

### 5. Method of Manufacturing Solid-State Imaging Device According to Second Embodiment

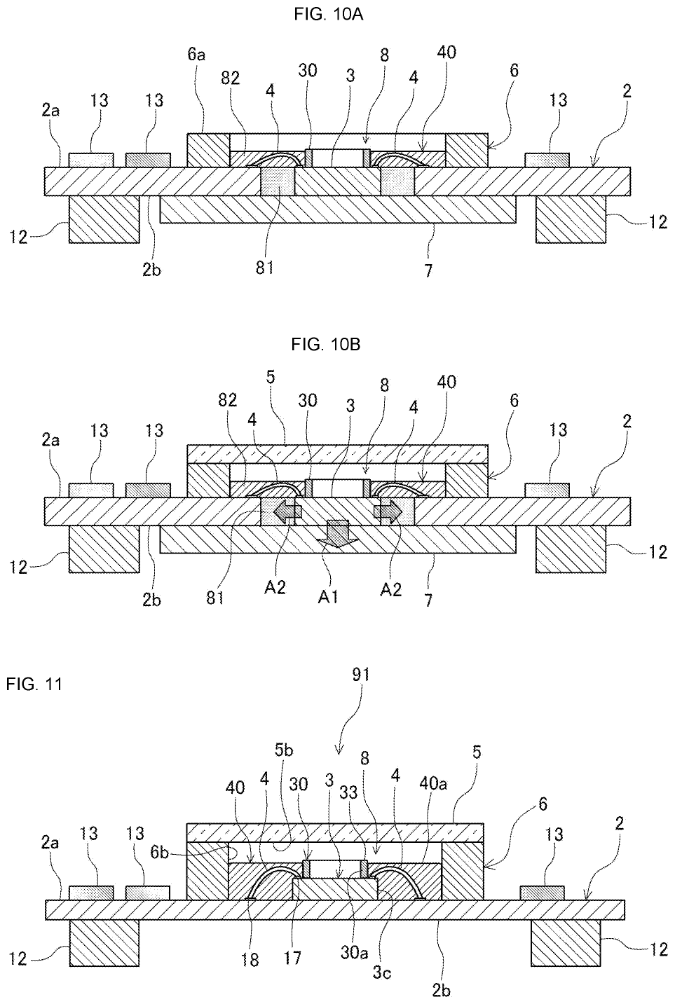

An example of a method of manufacturing the solid-state imaging device 71 according to the second embodiment will be described with reference to FIG. 9 and FIG. 10.

In the method of manufacturing the solid-state imaging device 71, as in the first embodiment, the substrate 2 having the opening 10 is prepared (see FIG. 2A), the process of forming the rib portion 6 on the substrate 2 is carried out (see FIG. 2B), and the process of providing the metal plate 7 onto the substrate 2 is carried out (see FIG. 2C). In addition, the process of mounting the connector 12 and the front surface component 13 is carried out (see FIG. 3A), and the process of mounting the image sensor 3 is carried out (see FIG. 3B). The processes up to the process of mounting the image sensor 3 are common to those in the first embodiment.

After the process of mounting the image sensor 3 is carried out, as illustrated in FIG. 9A, the process of forming the lower layer portion 81 is carried out. In this process, first, the space portion around the image sensor 3, that is, in the groove 15, the resin material having the first thermal conductivity and serving as the lower layer portion 81 is applied to a level of such a height as to fill the groove 15 in whole with a dispenser or the like. The resin material applied to the periphery of the image sensor 3 is solidified by heating, UV irradiation, or the like at a predetermined timing, and becomes the lower layer portion 81. Accordingly, the side surface portion 3c of the image sensor 3 is put into a state of being covered with the lower layer portion 81.

Next, as illustrated in FIG. 9B, the wire bonding process of providing the bonding wire 4 which electrically connects the image sensor 3 and the substrate 2 is carried out. Subsequently, as illustrated in FIG. 9C, the process of forming the bank-like resin portion 30 is carried out. It is to be noted that the process of forming the lower layer portion 81 may be carried out after the wire bonding process.

Subsequently, as illustrated in FIG. 10A, the process of forming the upper layer portion 82 is carried out. In this process, the resin material serving as the upper layer portion 82 and having the second thermal conductivity lower than the first thermal conductivity is applied to the space outside the bank-like resin portion 30 and inside the rib portion 6 to a level of such a height as to cover the bonding wire 4 in whole with a dispenser or the like. The resin material applied to the periphery of the image sensor 3 is solidified by heating, UV irradiation, or the like at a predetermined timing and becomes the upper layer portion 82. Accordingly, the covering resin portion 40 including the lower layer portion 81 and the upper layer portion 82 is formed.

Then, as illustrated in FIG. 10B, the process of mounting the glass 5 is carried out. Accordingly, the cavity 8 is formed above the image sensor 3. According to the manufacturing process described above, the solid-state imaging device 71 is obtained.

According to the solid-state imaging device 71 of the present embodiment described above, in addition to the advantageous effects obtained by the solid-state imaging device 1 of the first embodiment, the following advantageous effect is obtained. Specifically, the periphery of the image sensor 3 is put into a state of being covered with the lower layer portion 81 having a thermal conductivity higher than that of the upper layer portion 82, so that a much higher heat dissipation property can be obtained.

Particularly, the lower layer portion 81 secures the heat dissipation path (see arrows A2 in FIG. 10B) from the image sensor 3 to the lateral sides (to the side surface portions 3c), so that a high heat dissipation effect can be obtained. Accordingly, the metal plate 7 secures the heat dissipation path from the image sensor 3 toward the lower side thereof (toward the back surface 3b side) (see an arrow A1 in FIG. 10B), and the heat dissipation efficiency from the respective side surface portions 3c of the image sensor 3 in the four surrounding directions can be increased, so that a favorable heat dissipation property can be obtained. Thus, from the viewpoint of obtaining a favorable heat dissipation property from the image sensor 3, the lower layer portion 81 is favorably formed at least to a height from the upper surface 7a of the metal plate 7 to the front surface 3a of the image sensor 3, in such a manner as to cover the side surface portions 3c of the image sensor 3 in whole.

It is to be noted that, in the solid-state imaging device 71 according to the present embodiment, at least either the configuration of the first modification example or the configuration of the second modification example of the first embodiment can be adopted.

### 6. Configuration Example of Solid-State Imaging Device According to Third Embodiment

A configuration example of a solid-state imaging device 91 according to a third embodiment of the present technique will be described with reference to FIG. 11.

The solid-state imaging device 91 according to the present embodiment is different from that of the first embodiment in that the metal plate 7 is not included. In the solid-state imaging device 91, the substrate 2 does not have the opening 10 formed therein, and the image sensor 3 is mounted on the front surface 2a of the substrate 2 with the die bonding material or the like.

In the solid-state imaging device 91, the covering resin portion 40 is provided so as to fill the space between the rib portion 6 and the bank-like resin portion 30 and to cover the bonding wire 4. The covering resin portion 40 is formed so as to fill the space defined by the rib portion 6 and the glass 5 and formed on the substrate 2 around the image sensor 3, at a height position in a range of a height higher than the upper end of the bonding wire 4 to a height lower than the upper end surface 33 of the bank-like resin portion 30.

Thus, in the solid-state imaging device 91, the bank-like resin portion 30 is provided by the resin material having a relatively high viscosity in the peripheral region of the image sensor 3, and the covering resin portion 40 which covers all the portion on the inner side of the rib portion 6 on the front surface 2a of the substrate 2, the side surface portion 3c of the image sensor 3, and the bonding wire 4 together is provided outside the bank-like resin portion 30. In the solid-state imaging device 91, the cavity 8 is a space portion above the image sensor 3, and is formed by the bank-like resin portion 30, the upper surface 40a of the covering resin portion 40, the lower surface 5b of the glass 5, and the inner side surface 6b of the rib portion 6.

The method of manufacturing the solid-state imaging device 91 is a method of, for example, in the method of manufacturing the solid-state imaging device 1 of the first embodiment, omitting the process of attaching the metal plate 7 to the substrate 2 and setting the object on which the image sensor 3 is mounted to the substrate 2.

Thus, in the packaged structure not provided with the metal plate 7 on the back surface 2b side of the substrate 2, that is, also in the packaged structure that is not a metal-back structure, with the bank-like resin portion 30 and the covering resin portion 40 included therein, as in the solid-state imaging device 1 of the first embodiment, a favorable heat dissipation property can be obtained, and it is possible to prevent generation of noise such as a flare caused by the light reflected from such members as the bonding wire 4 being present at the periphery of the image sensor 3.

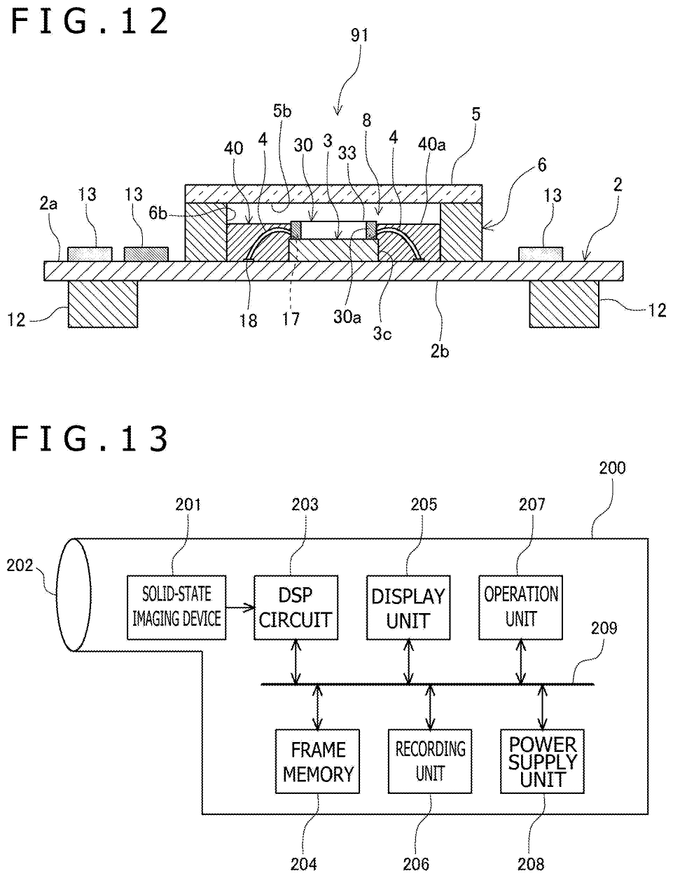

Also in the solid-state imaging device 91 according to the present embodiment, the configuration of the first modification example of the solid-state imaging device 1 according to the first embodiment can be adopted. Specifically, as illustrated in FIG. 12, in the solid-state imaging device 91, the bank-like resin portion 30 may be provided so as to cover the connecting portion of the bonding wire 4 for the pad electrode 17 of the image sensor 3. Adopting such a configuration enables the peripheral region of the front surface 3a of the image sensor 3 to be reduced, thereby enhancing a yield of the image sensor 3. In addition, in the solid-state imaging device 91 according to the present embodiment, the configuration of the second modification example of the first embodiment can be adopted.

### 7. Configuration Example of Electronic Equipment

An application example of any one of the solid-state imaging devices according to the embodiments described above to electronic equipment will be described with reference to FIG. 13.

The solid-state imaging device according to the present technique is applicable to pieces of electronic equipment in general each including the solid-state imaging element as an image pickup unit (photoelectric conversion unit), such as a camera apparatus like a digital still camera, a video camera, or the like, a portable terminal device having an imaging function, and a copying machine including the solid-state imaging element as an image reading unit. The solid-state imaging device may have a one-chip form, or a module-shaped form having an imaging function as a package collectively including an imaging unit and a signal processing unit or an optical system.

As illustrated in FIG. 13, the camera apparatus 200 as electronic equipment includes an optical unit 202, the solid-state imaging device 201, a DSP (Digital Signal Processor) circuit 203 which is a camera signal processing circuit, a frame memory 204, a display unit 205, a recording unit 206, an operation unit 207, and a power supply unit 208. The DSP circuit 203, the frame memory 204, the display unit 205, the recording unit 206, the operation unit 207, and the power supply unit 208 are appropriately connected to one another via a connection line 209 such as a bus line. The solid-state imaging device 201 is, for example, the solid-state imaging device 1 according to the first embodiment described above.

The optical unit 202 includes multiple lenses and captures incident light (image light) coming from a subject, to form an image of the incident light on an imaging surface of the solid-state imaging device 201. After the image of the incident light is formed on the imaging surface by the optical unit 202, the solid-state imaging device 201 converts light quantities of the incident light into electric signals for each pixel and outputs the electric signals as pixel signals.

For example, the display unit 205 includes a panel-type display device such as a liquid crystal panel and an organic EL (Electro Luminescence) panel and displays moving images or still images captured by the solid-state imaging device 201. The recording unit 206 records the moving images or the still images captured by the solid-state imaging device 201 in a recording medium such as a hard disk and a semiconductor memory.

The operation unit 207 issues, on the basis of an operation by a user, an operation instruction for various functions of the camera apparatus 200. The power supply unit 208 appropriately supplies various types of power sources which are operation power sources of the DSP circuit 203, the frame memory 204, the display unit 205, the recording unit 206, and the operation unit 207 to these supply targets.

According to the camera apparatus 200 described above, as for the solid-state imaging device 201, it is possible to obtain a favorable heat dissipation property, and prevent the material from falling off from the side surface portion 10a of the substrate 2, and prevent generation of noise such as a flare caused by light reflected from the members around the image sensor 3. Hence, in the camera apparatus 200, it is possible to hold a favorable operation state and obtain a desired characteristic.

The respective embodiments described above are presented only as examples of the present technique. It is not intended that the present technique be limited to the above embodiments. Accordingly, in addition to the respective embodiments described above, it is obvious that various modifications may be made according to designs and the like without departing from the technical ideas of the present disclosure. Moreover, advantageous effects are not limited to those described in the present disclosure as mere examples. In addition, other advantageous effects may be produced. In addition, the configurations of the embodiments and the configuration of the modification examples described above can be used in combination as needed.

In the embodiments described above, as the support metal portion which supports the image sensor 3 to the substrate 2, the configuration provided with the metal plate 7 that is a plate-shaped member is adopted. However, the support metal portion according to the present technique is not limited to such a configuration described above. Regarding the support metal portion according to the present technique, as the configuration for increasing the heat dissipation property from the semiconductor element, for example, such a configuration that a casing including metal is provided on the back side of the substrate may be applicable.

It is to be noted that the present technique can adopt the following configurations.

(1)

A semiconductor device including:
a substrate;
a semiconductor element which is electrically connected to the substrate;
a connecting member which electrically connects the substrate with the semiconductor element;
a support portion which is provided on the substrate and supports a transparent member being located above the semiconductor element with respect to the substrate;
a first resin portion provided on the semiconductor element; and
a second resin portion which fills a space between the support portion and the first resin portion and covers the connecting member.
   (2)

The semiconductor device according to (1) above, further including:
a support metal portion which is provided on a back surface side of the substrate and supports the semiconductor element with respect to the substrate.
   (3)

The semiconductor device according to (1) or (2) above, in which
the first resin portion is provided so as to cover a connecting portion of the connecting member for the semiconductor element.
   (4)

The semiconductor device according to any one of (1) to (3) above, in which
the semiconductor element has a pixel region including a large number of pixels on a front surface thereof and a peripheral region which is a region outside the pixel region and has a step formed on a side lower than the pixel region, and
the first resin portion is provided on the peripheral region.
   (5)

The semiconductor device according to any one of (1) to (4) above, in which
the second resin portion has a lower layer portion which covers a side surface of the semiconductor element, and an upper layer portion formed on the lower layer portion and covering the connecting member, and
the lower layer portion is formed by a material having a thermal conductivity higher than that of the upper layer portion.
   (6)

Electronic equipment including:
a semiconductor device including
   a substrate,
   a semiconductor element which is electrically connected to the substrate,
   a connecting member which electrically connects the substrate with the semiconductor element,
   a support portion which is provided on the substrate and supports a transparent member being located above the semiconductor element with respect to the substrate,
   a first resin portion provided on the semiconductor element, and
   a second resin portion which fills a space between the support portion and the first resin portion and covers the connecting member.

### REFERENCE SIGNS LIST

1: Solid-state imaging device (semiconductor device)
2: Substrate
2a: Front surface
2b: Back surface
3: Image sensor (semiconductor element)
3a: Front surface
3c: Side surface portion
4: Bonding wire (connecting member)
5: Glass (transparent member)
6: Rib portion (support portion)
7: Metal plate (support metal portion)
10: Opening
10a: Side surface portion
17: Pad electrode
18: Lead electrode
30: Bank-like resin portion (first resin portion)
40: Covering resin portion (second resin portion)
41: Groove filling portion
42: Wire covering portion
51: Pixel region
52: Peripheral region
65: Layered structure
71: Solid-state imaging device (semiconductor device)
81: Lower layer portion
82: Upper layer portion
91 Solid-state imaging device (semiconductor device)
200: Camera apparatus (electronic equipment)
201: Solid-state imaging device (semiconductor device)

1. A semiconductor device comprising:
a substrate;
a semiconductor element which is electrically connected to the substrate;
a connecting member which electrically connects the substrate with the semiconductor element;
a support portion which is provided on the substrate and supports a transparent member being located above the semiconductor element with respect to the substrate;
a first resin portion provided on the semiconductor element; and
a second resin portion which fills a space between the support portion and the first resin portion and covers the connecting member.

2. The semiconductor device according to claim 1, further comprising:
a support metal portion which is provided on a back surface side of the substrate and supports the semiconductor element with respect to the substrate.

3. The semiconductor device according to claim 1, wherein
the first resin portion is provided so as to cover a connecting portion of the connecting member for the semiconductor element.

4. The semiconductor device according to claim 1, wherein
the semiconductor element has a pixel region including a large number of pixels on a front surface thereof and a peripheral region which is a region outside the pixel region and has a step formed on a side lower than the pixel region, and
the first resin portion is provided on the peripheral region.

5. The semiconductor device according to claim 1, wherein
the second resin portion has a lower layer portion which covers a side surface of the semiconductor element, and an upper layer portion formed on the lower layer portion and covering the connecting member, and
the lower layer portion is formed by a material having a thermal conductivity higher than that of the upper layer portion.

6. Electronic equipment comprising:
a semiconductor device including
a substrate,
a semiconductor element which is electrically connected to the substrate,
a connecting member which electrically connects the substrate with the semiconductor element,
a support portion which is provided on the substrate and supports a transparent member being located above the semiconductor element with respect to the substrate,
a first resin portion provided on the semiconductor element, and
a second resin portion which fills a space between the support portion and the first resin portion and covers the connecting member.
